(19) United States
(12) Patent Application Publication
(10) Pub. No.: US 2005/0285206 A1
(43) Pub. Date: Dec. 29, 2005

(54) Semiconductor device and manufacturing method thereof

(75) Inventors: Masaru Kadoshima, Tsukuba (JP); Toshihide Nabatame, Tsukuba (JP)

Correspondence Address: Stanley P. Fisher;Reed Smith LLP, 3110 Fairview Park Drive, Suite 1400, Falls Church, VA, 22042-4503, US

(73) Assignee: Renesas Technology Corp.

(21) Appl. No.: 11/142,796

(22) Filed: Jun. 2, 2005

(30) Foreign Application Priority Data
Jun. 29, 2004 (JP) 2004-190589

(51) Int. Cl. H01L 29/78; H01L 21/8238

(52) U.S. Cl. 257/369; 257/412; 438/592; 438/199; 438/682

(57) ABSTRACT

The performance and reliability of a semiconductor device are improved. In a semiconductor device having a CMISFET, a gate electrode of an n channel MISFET is comprised of metal silicide containing Ni, metal with a work function lower than that of Ni, and Si, and a gate electrode of a p channel MISFET is comprised of metal silicide containing Ni, metal with a work function higher than that of Ni, and Si. Since metal with a work function lower than that of Ni is contained in the gate electrode of the n channel MISFET and metal with a work function higher than that of Ni is contained in the gate electrode of the p channel MISFET, the threshold voltage can be reduced in both the n channel MISFET and the p channel MISFET. Also, the gate electrodes are formed by reacting a nondope silicon film with a metal film.

### CROSS-REFERENCE TO RELATED APPLICATION

The present application claims priority from Japanese Patent Application No. JP 2004-190589 filed on Jun. 29, 2004, the content of which is hereby incorporated by reference into this application.

### TECHNICAL FIELD OF THE INVENTION

The present invention relates to a semiconductor device and a manufacturing method thereof. More particularly, the present invention relates to a technology effectively applied to a semiconductor device in which a gate electrode of a MISFET is comprised of metal silicide and a manufacturing method thereof.

### BACKGROUND OF THE INVENTION

After forming a gate insulating film on a semiconductor substrate and forming a gate electrode on the gate insulating film, source and drain regions are formed by the ion implantation or the like. Through the process described above, a MISFET (Metal Insulator Semiconductor Field Effect Transistor, MIS field effect transistor, MIS transistor) is formed.

Also, in the CMISFET (Complementary Metal Insulator Semiconductor Field Effect Transistor), in order to realize the low threshold voltage in both of the n channel MISFET and the p channel MISFET, the so-called dual-gate structure in which materials having different work functions (Fermi level, in the case of polysilicon) are used to form the gate electrodes has been employed. More specifically, an n type impurity and a p type impurity are introduced into the respective polysilicon films of the n channel MISFET and the p channel MISFET so that the work function (Fermi level) of the gate electrode material of the n channel MISFET becomes close to the conduction band of silicon and the work function (Fermi level) of the gate electrode material of the p channel MISFET becomes close to the valence band of silicon. By doing so, the threshold voltage is reduced.

However, the thickness of a gate insulating film has been reduced more and more due to the scaling down of the CMISFET device in recent years, and the influence of the depletion in the gate electrode when a polysilicon film is used for the gate electrode has become a significant problem. For the solution of the problem, there is the technology of using a metal gate electrode as the gate electrode for preventing the depletion in the gate electrode.

U.S. Pat. No. 6,599,831 B1 describes the technology in which a polysilicon film doped with a dopant is reacted with a nickel layer formed thereon to form a gate electrode comprised of nickel silicide.

### SUMMARY OF THE INVENTION

As a result of the examination by the inventors of the present invention, the following problems are found out.

In the case where a polysilicon film is used as a gate electrode of a MISFET, influence of the depletion in the gate electrode comprised of polysilicon occurs in many cases. However, when a metal material such as nickel silicide is used to form the gate electrode, the depletion in the gate electrode can be suppressed and the parasitic capacitance can be removed. Consequently, the scaling down of the MISFET device (thickness reduction of gate insulating film) can be achieved.

However, even in the case where a metal film such as nickel silicide is used as the gate electrode material, the reduction of the threshold voltage in both of the n channel MISFET and the p channel MISFET of the CMISFET is desired for the improvement of the performance of the semiconductor device. For its achievement, it is necessary to control the work function of the gate electrodes of the n channel MISFET and the p channel MISFET.

In the technology in which a polysilicon film doped with a dopant is reacted with a nickel layer formed thereon to form a gate electrode comprised of nickel silicide, the threshold voltage can be controlled by the dopant. However, in the thermal treatment, for example, the annealing for activating an impurity, boron (B) doped into a polysilicon film for forming a gate electrode of the p channel MISFET penetrates through the gate insulating film and diffuses into a channel region below the gate insulating film, and as a result, the characteristics and the reliability of the formed CMISFET may be influenced.

An object of the present invention is to provide a technology capable of improving the performance of a semiconductor device.

Another object of the present invention is to provide a technology capable of improving the reliability of a semiconductor device.

The above and other objects and novel characteristics of the present invention will be apparent from the description and the accompanying drawings of this specification.

The typical ones of the inventions disclosed in this application will be briefly described as follows.

The present invention is a semiconductor device, which comprises: an n channel first MISFET; and a p channel second MISFET, wherein a first gate electrode of the first MISFET is comprised of metal silicide containing Ni, first metal with a work function lower than that of Ni, and Si, and a second gate electrode of the second MISFET is comprised of metal silicide containing Ni, second metal with a work function higher than that of Ni, and Si.

A method of manufacturing a semiconductor device having an n channel first MISFET and a p channel second MISFET, which comprises steps of: (a) preparing a semiconductor substrate; (b) forming a first insulating film for a gate insulating film on the semiconductor substrate; (c) forming a silicon film on the first insulating film; (d) forming a first dummy electrode of the first MISFET and a second dummy electrode of the second MISFET by patterning the silicon film; (e) forming a first metal film containing Ni and first metal with a work function lower than that of Ni on the first dummy electrode; (f) reacting the silicon film constituting the first dummy electrode with the first metal film to form a first gate electrode of the first MISFET, which is comprised of metal silicide containing Ni, the first metal, and Si; (g) forming a second metal film containing Ni and second metal with a work function higher than that of Ni on the second dummy electrode; and (h) reacting the silicon film constituting the second dummy electrode with the second metal film to form a second gate electrode of the second MISFET, which is comprised of metal silicide containing Ni, the second metal, and Si.

A method of manufacturing a semiconductor device having an n channel first MISFET and a p channel second MISFET, which comprises steps of: (a) preparing a semiconductor substrate; (b) forming a first insulating film for a gate insulating film on the semiconductor substrate; (c) forming a silicon film on the first insulating film; (d) forming a first dummy electrode of the first MISFET and a second dummy electrode of the second MISFET by patterning the silicon film; (e) forming a metal film mainly comprised of nickel on the first dummy electrode and the second dummy electrode; (f) introducing first metal with a work function lower than that of Ni into the metal film on the first dummy electrode and introducing second metal with a work function higher than that of Ni into the metal film on the second dummy electrode by ion implantation, and (g) reacting the silicon film constituting the first dummy electrode with the metal film in which the first metal is introduced to form a first gate electrode of the first MISFET comprised of metal silicide containing Ni, the first metal, and Si, and reacting the silicon film constituting the second dummy electrode with the metal film in which the second metal is introduced to form a second gate electrode of the second MISFET comprised of metal silicide containing Ni, the second metal, and Si.

A method of manufacturing a semiconductor device having an n channel first MISFET and a p channel second MISFET, which comprises steps of: (a) preparing a semiconductor substrate; (b) forming a first insulating film for a gate insulating film on the semiconductor substrate; (c) forming a silicon film on the first insulating film; (d) forming a first dummy electrode of the first MISFET and a second dummy electrode of the second MISFET by patterning the silicon film; (e) forming a metal film mainly comprised of nickel on the first dummy electrode and the second dummy electrode; (f) reacting the silicon film constituting the first dummy electrode with the metal film to form a first gate electrode of the first MISFET comprised of nickel silicide, and reacting the silicon film constituting the second dummy electrode with the metal film to form a second gate electrode of the second MISFET comprised of nickel silicide; and (g) introducing first metal with a work function lower than that of Ni into the first gate electrode and introducing second metal with a work function higher than that of Ni into the second gate electrode by ion implantation.

The effect obtained by the representative one of the inventions disclosed in this application will be briefly described as follows.

That is, it is possible to improve the performance of a semiconductor device.

Also, it is possible to improve the reliability of a semiconductor device.

### BRIEF DESCRIPTIONS OF THE DRAWINGS

FIG. 1 is a cross-sectional view showing the principal part in the process of manufacturing a semiconductor device according to an embodiment of the present invention;

FIG. 2 is a cross-sectional view showing the principal part in the process of manufacturing a semiconductor device subsequent to FIG. 1;

FIG. 3 is a cross-sectional view showing the principal part in the process of manufacturing a semiconductor device subsequent to FIG. 2;

FIG. 4 is a cross-sectional view showing the principal part in the process of manufacturing a semiconductor device subsequent to FIG. 3;

FIG. 5 is a cross-sectional view showing the principal part in the process of manufacturing a semiconductor device subsequent to FIG. 4;

FIG. 6 is a cross-sectional view showing the principal part in the process of manufacturing a semiconductor device subsequent to FIG. 5;

FIG. 7 is a cross-sectional view showing the principal part in the process of manufacturing a semiconductor device subsequent to FIG. 6;

FIG. 8 is a cross-sectional view showing the principal part in the process of manufacturing a semiconductor device subsequent to FIG. 7;

FIG. 9 is a cross-sectional view showing the principal part in the process of manufacturing a semiconductor device subsequent to FIG. 8;

FIG. 10 is a cross-sectional view showing the principal part in the process of manufacturing a semiconductor device subsequent to FIG. 9;

FIG. 11 is a cross-sectional view showing the principal part in the process of manufacturing a semiconductor device subsequent to FIG. 10;

FIG. 12 is a cross-sectional view showing the principal part in the process of manufacturing a semiconductor device subsequent to FIG. 11;

FIG. 13 is a graph showing the correlation between the solid solubility of Ti and the change in flat band voltage;

FIG. 14 is a graph showing the correlation between the solid solubility of Pt and the change in flat band voltage;

FIG. 15 is a cross-sectional view showing the principal part in the process of manufacturing a semiconductor device according to another embodiment of the present invention;

FIG. 16 is a cross-sectional view showing the principal part in the process of manufacturing a semiconductor device subsequent to FIG. 15;

FIG. 17 is a cross-sectional view showing the principal part in the process of manufacturing a semiconductor device subsequent to FIG. 16;

FIG. 18 is a cross-sectional view showing the principal part in the process of manufacturing a semiconductor device subsequent to FIG. 17;

FIG. 19 is a cross-sectional view showing the principal part in the process of manufacturing a semiconductor device subsequent to FIG. 18;

FIG. 20 is a cross-sectional view showing the principal part in the process of manufacturing a semiconductor device subsequent to FIG. 19;

FIG. 21 is a cross-sectional view showing the principal part in the process of manufacturing a semiconductor device according to another embodiment of the present invention;

FIG. 22 is a cross-sectional view showing the principal part in the process of manufacturing a semiconductor device subsequent to FIG. 21;

FIG. 23 is a cross-sectional view showing the principal part in the process of manufacturing a semiconductor device subsequent to FIG. 22;

FIG. 24 is a cross-sectional view showing the principal part in the process of manufacturing a semiconductor device subsequent to FIG. 23;

FIG. 25 is a cross-sectional view showing the principal part in the process manufacturing of a semiconductor device subsequent to FIG. 24; and

FIG. 26 is a cross-sectional view showing the principal part in the process of manufacturing a semiconductor device subsequent to FIG. 25.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted. Also, the description of the same and similar part is not repeated in principle unless particularly required in the following embodiments.

Also, in the drawings used in the embodiments, the hatching is omitted in some cases even in a cross-sectional view and the hatching is used in some cases even in a plan view so as to make the drawings easy to see.

### First Embodiment

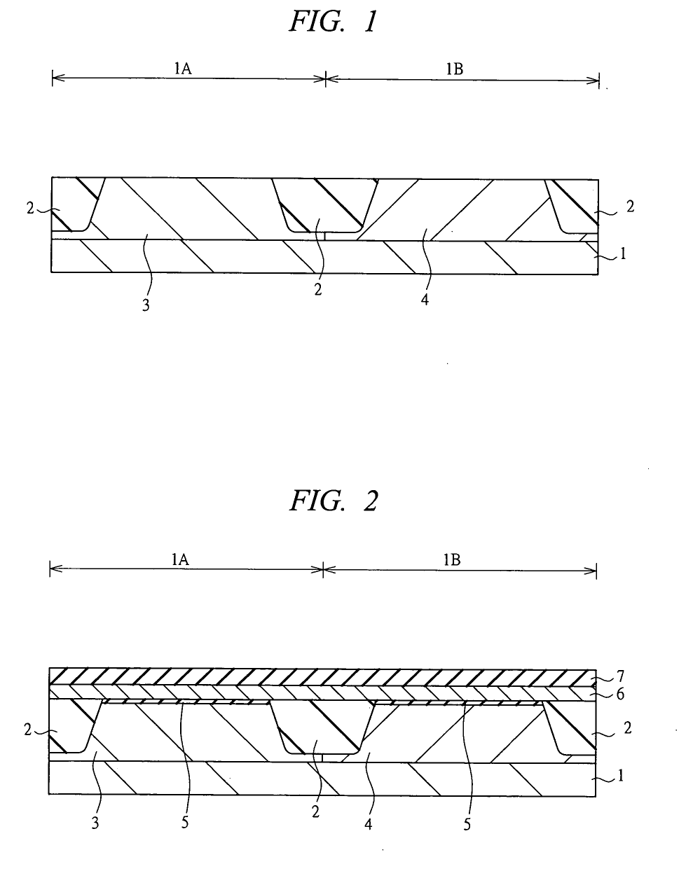

A semiconductor device and a manufacturing method thereof according to this embodiment will be described with reference to the drawings. FIGS. 1 to 12 are cross-sectional views showing the principal part in the process of a manufacturing of a semiconductor device according to an embodiment of the present invention, for example, a CMISFET (Complementary Metal Insulator Semiconductor Field Effect Transistor).

As shown in FIG. 1, a semiconductor substrate (semiconductor wafer) 1 comprised of p type single crystal silicon with a specific resistance of about 1 to 10 Ωcm is prepared. The semiconductor substrate 1 on which the semiconductor device according to this embodiment is to be formed has an n channel MISFET forming region 1A in which an n channel MISFET (Metal Insulator Semiconductor Field Effect Transistor) is formed and a p channel MISFET forming region 1B in which a p channel MISFET is formed. Then, device isolation regions 2 are formed in the main surface of the semiconductor substrate 1. The device isolation region 2 is composed of an insulator such as silicon oxide and is formed by, for example, the STI (Shallow Trench Isolation) method or the LOCOS (Local Oxidation of Silicon) method.

Next, a p type well 3 is formed in a region of the semiconductor substrate 1 in which the n channel MISFET is to be formed (n channel MISFET forming region 1A), and an n type well 4 is formed in a region of the semiconductor substrate 1 in which the p channel MISFET is to be formed (p channel MISFET forming region 1B). The p type well 3 is formed by the ion implantation of a p type impurity such as boron (B), and the n type well 4 is formed by the ion implantation of an n type impurity such as phosphorus (P) or arsenic (As).

Next, as shown in FIG. 2, a gate insulating film 5 is formed on the surfaces of the p type well 3 and the n type well 4. The gate insulating film 5 is composed of, for example, a thin silicon oxide film and can be formed by, for example, the thermal oxidation method. When a silicon oxide film is used as the gate insulating film 5, the thickness thereof can be, for example, about 2 to 4 nm. In addition, it is also possible to use a silicon oxynitride film as the gate insulating film 5. Furthermore, it is also possible to use the so-called High-k (high dielectric constant) film comprised of, for example, hafnium oxide (HfO₂), hafnium aluminate (HfAlOₓ), hafnium silicate (HfSiOₓ), zirconia (zirconium oxide), zirconium aluminate (ZrAlOₓ), zirconium silicate (ZrSiOₓ), lanthanum oxide (La₂O₃), or lanthanum silicate (LaSiOₓ).

Next, a silicon film 6 is formed on the gate insulating film 5. The silicon film 6 is, for example, a polycrystalline silicon film and can be formed by the CVD (Chemical Vapor Deposition) method. When the CVD method is used as the method of forming the silicon film 6, the silicon film 6 can be formed without damaging the gate insulating film 5 and the like. The thickness of the silicon film 6 can be, for example, about 20 to 30 nm. Also, an amorphous silicon film can be used as the silicon film 6. Also, the silicon film 6 is preferably a nondope (undope) silicon film in which no impurity is introduced (nondope polysilicon film or nondope amorphous silicon film). Note that, in this embodiment, the nondope means that any impurity is not introduced (added) intentionally, and the nondope includes the case where a minute amount of impurity is contained unintentionally.

Next, an insulating film (hard mask layer) 7 comprised of silicon oxide is formed on the silicon film 6. The thickness of the insulating film 7 can be, for example, about 50 to 100 nm.

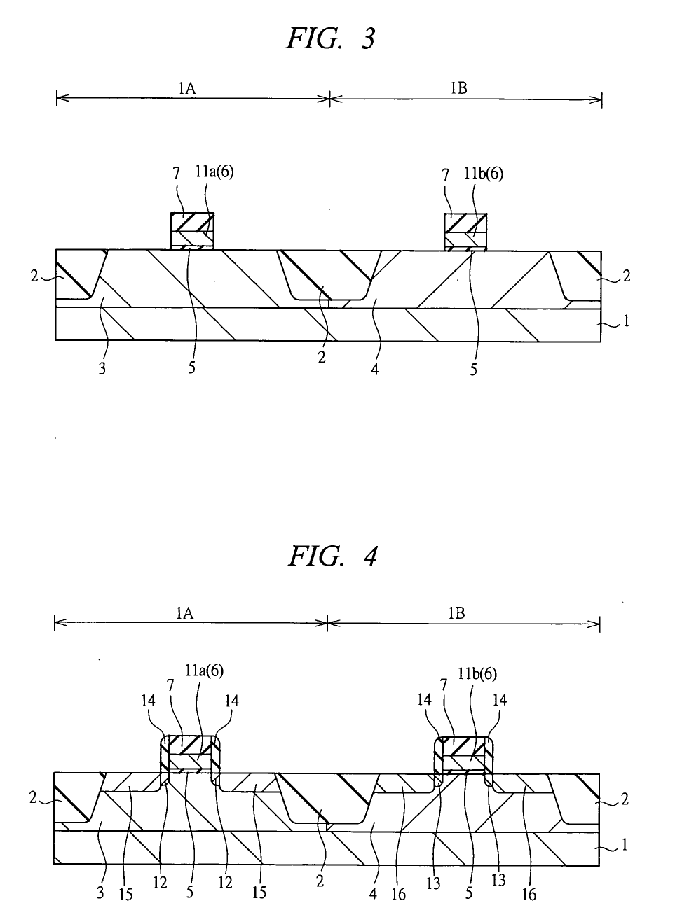

Next, as shown in FIG. 3, a laminated film composed of the silicon film 6 and the insulating film 7 is formed through the patterning process (patterning, processing, selective removal) using the photolithography method and the dry etching method. For example, the reactive ion etching (RIE) is used in this patterning process. The patterned silicon film 6 forms dummy gate electrodes (dummy electrode) 11a and 11b. More specifically, the dummy gate electrode 11a for the n channel MISFET is composed of the silicon film 6 on the gate insulating film 5 on the surface of the p type well 3, and the dummy gate electrode 11b for the p channel MISFET is composed of the silicon film 6 on the gate insulating film 5 on the surface of the n type well 4. The gate electrodes 11a and 11b are to be metal gate electrodes (gate electrodes 31a and 31b) of the MISFETs through the silicidation process (salicidation process) described later.

Next, as shown in FIG. 4, an n type impurity such as phosphorus (P) or arsenic (As) is ion-implanted into the regions on both sides of the gate electrode 11a of the p type well 3 to form (a pair of) n⁻ type semiconductor regions 12 aligned with the gate electrode 11a of the p type well 3. Then, a p type impurity such as boron (B) is ion-implanted into the regions on both sides of the gate electrode 11b of the n type well 4 to form (a pair of) p⁻ type semiconductor regions 13 aligned with the gate electrode 11b of the n type well 4. Since the insulating film 7 exists on the gate electrodes 11a and 11b and the insulating film 7 functions as a mask in the ion implantation process described above, the impurity ions are not introduced into the gate electrodes 11a and 11b.

Next, sidewalls (sidewall spacer, sidewall insulating film) 14 comprised of an insulator such as silicon nitride are formed on the sidewalls of the gate electrodes 11a and 11b. The sidewalls 14 are formed by depositing a silicon nitride film on the semiconductor substrate 1 and then performing the anisotropic etching of the silicon nitride film.

After forming the sidewalls 14, the ion implantation of an n type impurity such as phosphorus (P) or arsenic (As) into the regions on both sides of the gate electrode 11a and the sidewalls 14 of, for example, the p type well 3 is performed to form (a pair of) n⁺ type semiconductor regions 15 (source, drain) aligned with the sidewalls 14 of the gate electrode 11a of the p type well 3, and the ion implantation of a p type impurity such as boron (B) into the regions on both sides of the gate electrode 11b and the sidewalls 14 of, for example, the n type well 4 is performed to form (a pair of) p⁺ type semiconductor regions 16 (source, drain) aligned with the sidewalls 14 of the gate electrode 11b of the n type well 4. Since the insulating film 7 exists on the gate electrodes 11a and 11b and the insulating film 7 functions as a mask in the ion implantation process described above, the impurity ions are not introduced into the gate electrodes 11a and 11b.

After the ion implantation, the annealing process for activating the introduced impurity (activation annealing, thermal treatment) is performed. By the annealing process at, for example, about 950° C., the impurity introduced into the n⁻ type semiconductor region 12, the p⁻ type semiconductor region 13, the n⁺ type semiconductor region 15, and the p⁺ type semiconductor region 16 can be activated. In the case where the silicon film 6 is an amorphous silicon film when it is formed, the silicon film 6 composed of an amorphous silicon film become may be a polycrystalline silicon film by this annealing process.

Also, in the case where the silicon film 6 constituting the gate electrodes 11a and 11b is the silicon film doped with an impurity, more particularly, in the case where the silicon film 6 constituting the gate electrode 11b is the silicon film doped with boron (B) (for example, B doped polysilicon film), there is the possibility that the boron (B) penetrates through the gate insulating film 5 and diffuses into the channel region below the gate insulating film 5 in this annealing process. However, since the nondope silicon film not doped with any impurity is used as the silicon film 6 constituting the gate electrodes 11a and 11b in this embodiment as described above, it is possible to prevent an impurity such as boron (B) from penetrating through the gate insulating film 5 and diffusing into the channel region below the gate insulating film 5 in this annealing process.

By the annealing process (activation annealing) described above, the impurities introduced into the n⁺ type semiconductor region 12, the p⁻ type semiconductor region 13, the n⁺ type semiconductor region 15, and the p⁺ type semiconductor region 16 are activated. As a result, n type semiconductor regions (impurity diffusion layer) functioning as the source or drain of the n channel MISFET are composed of the n⁺ type semiconductor region 15 and the n⁻ type semiconductor region 12, and p type semiconductor regions (impurity diffusion layer) functioning as the source or drain of the p channel MISFET are composed of the p⁺ type semiconductor region 16 and the p⁻ type semiconductor region 13. The impurity concentration of the n⁺ type semiconductor region 15 is higher than that of the n⁻ type semiconductor region 12, and the impurity concentration of the p⁺ type semiconductor region 16 is higher than that of the p⁻ type semiconductor region 13.

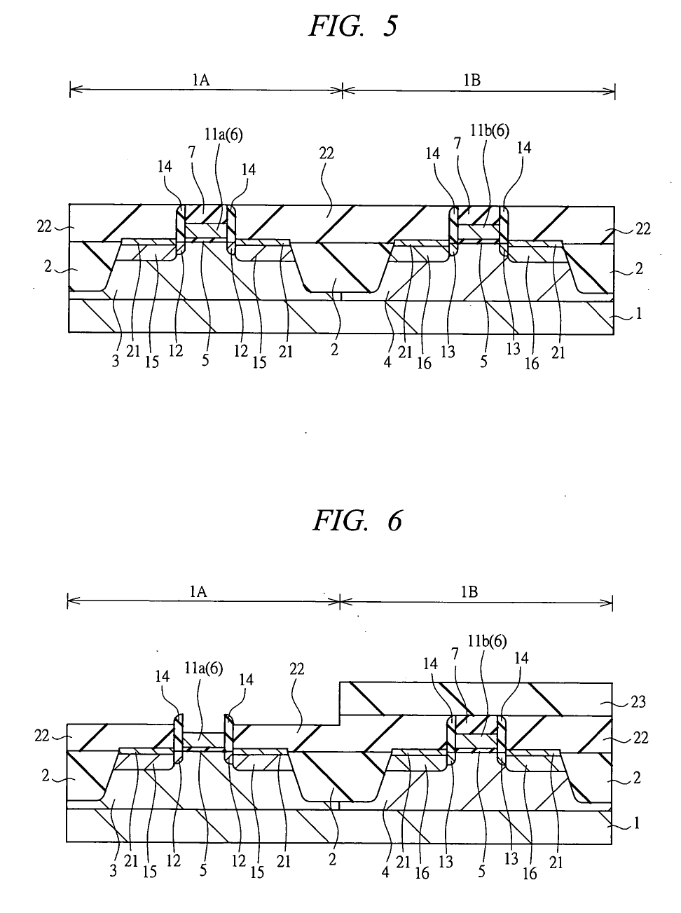

Next, as shown in FIG. 5, the etching (for example, wet etching using dilute hydrofluoric acid) is performed according to need to expose the surfaces of the n⁺ type semiconductor region 15 and the p⁺ type semiconductor region 16 (at this time, the insulating film 7 on the gate electrodes 11a and 11b is not removed so as not to expose the surfaces of the gate electrodes 11a and 11b). Thereafter, a metal film such as a cobalt (Co) film is deposited on the semiconductor substrate 1 including on the n⁺ type semiconductor region 15 and the p⁺ type semiconductor region 16, and then, the thermal treatment of the metal film is performed. By doing so, a metal silicide film (cobalt silicide film) 21 is formed on each of the surfaces of the n⁺ type semiconductor region 15 and the p⁺ type semiconductor region 16. This metal silicide film 21 can reduce the diffusion resistance and the contact resistance of the source and drain. Thereafter, the unreacted metal film (cobalt film) is removed. At this time, since the insulating film 7 exists on the gate electrodes 11a and 11b, the metal silicide film is not formed on the surfaces of the gate electrodes 11a and 11b. Although it is possible to reduce the diffusion resistance and the contact resistance by forming the metal silicide film 21 on the surfaces of the n⁺ type semiconductor region 15 and the p⁺ type semiconductor region 16, the step of forming the metal silicide film 21 can be omitted if the metal silicide film 21 is not necessary.

Next, an insulating film 22 is formed on the semiconductor substrate 1. More specifically, the insulating film 22 is formed on the semiconductor substrate 1 so as to cover the gate electrodes 11a and 11b. The insulating film 22 is composed of, for example, a silicon oxide film (for example, TEOS (Tetraethoxysilane oxide film)). When the process for forming the insulating film 22 is performed at a relatively high temperature, a cobalt silicide film is preferably used as the metal silicide film 21. However, when the process for forming the insulating film 22 is performed at a relatively low temperature, a nickel silicide film is also available as the metal silicide film 21.

Next, the upper surface of the insulating film 22 is planarized by the CMP (Chemical Mechanical Polishing) method to expose the surface of the insulating film 7. After the CMP method, the structure shown in FIG. 5 is obtained.

Next, as shown in FIG. 6, after forming an insulating film (etching mask layer) 23 which covers the p channel MISFET forming region 1B but not covers the n channel MISFET forming region 1A on the insulating film 22, the insulating film 7 on the gate electrode 11a is etched and removed to expose the surface (upper surface) of the gate electrode 11a. For example, the insulating film 7 on the gate electrode 11a can be removed by the wet etching using hydrofluoric acid. Since the thickness of the insulating film 22 is larger than that of the insulating film 7, the insulating film 22 is not completely removed even when the insulating film 7 on the gate electrode 11a is etched and removed. In addition, since a material different from that of the insulating film 7 is used to form the sidewalls 14, that is, a silicon oxide film is used to form the insulating film 7 and a silicon nitride film is used to form the sidewalls 14, the sidewalls 14 are not removed when the insulating film 7 on the gate electrode 11a is etched and removed. Also, since the p channel MISFET forming region 1B is covered with the insulating film 23, the insulating film 7 on the gate electrode 11b is not removed.

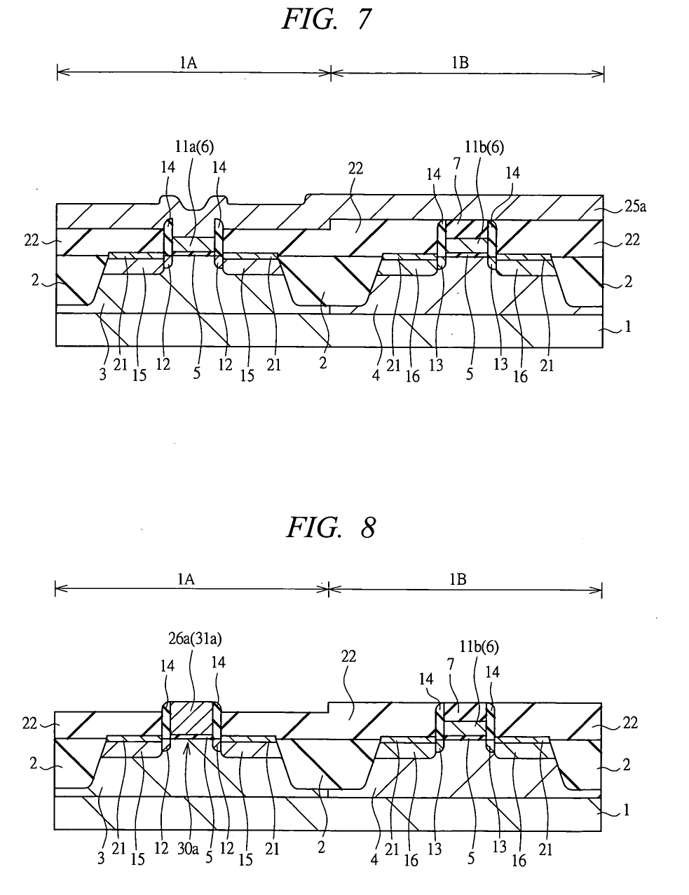

Next, as shown in FIG. 7, after removing the insulating film 23, a metal film 25a is formed on the semiconductor substrate 1. More specifically, the metal film 25a is formed on the semiconductor substrate 1 including on the upper surface of the gate electrode 11a. The metal film 25a can be formed by, for example, the sputtering method. Since the metal film 25a is formed after removing the insulating film 7 on the gate electrode 11a to expose the surface (upper surface) of the gate electrode 11a as described above, the upper surface of the gate electrode 11a composed of the silicon film 6 is brought into contact with the metal film 25a.

The metal film 25a is composed of an Ni (nickel) film in which metal with a work function lower than that of Ni (nickel) (for example, Ti (titanium), Hf (hafnium), Zr (zirconium), Ta (tantalum)) is solid-solved. More specifically, the metal film 25a is a metal film which contains metal with a work function lower than that of Ni (nickel) (for example, Ti (titanium), Hf (hafnium), Zr (zirconium), Ta (tantalum)) and Ni (nickel). For example, it is a film comprised of metal alloy of metal with a work function lower than that of Ni and Ni.

Next, as shown in FIG. 8, after forming the metal film 25a, the metal film 25a is reacted with the gate electrodes 11a (silicon film 6) by the thermal treatment to form a metal silicide film (conductive film) 26a. For example, by the thermal treatment at about 400° C. in the nitrogen gas atmosphere, the metal film 25a is reacted with the gate electrode 11a (silicon film 6) to form the metal silicide film 26a. At this time, all of the silicon film 6 constituting the gate electrode 11a is completely reacted with the metal film 25a to form the metal silicide film 26a. Thereafter, the unreacted metal film 25a is removed. For example, the unreacted metal film 25a can be removed by the SPM process (process using sulfuric acid (H₂SO₄)/hydrogen peroxide (H₂O₂)/water (H₂O) solution (SPM)).

As described above, since the metal film 25a is composed of an Ni film in which the metal (metal element) with a work function lower than that of Ni is solid-solved, the metal silicide film 26a formed by the reaction between the metal film 25a and the silicon film 6 constituting the gate electrode 11a is composed of a metal silicide film containing (as constituent elements) Ni (nickel), metal with a work function lower than that of Ni (for example, Ti (titanium), Hf (hafnium), Zr (zirconium), or Ta (tantalum)), and Si (silicon). For example, it is comprised of alloy of metal with a work function lower than that of Ni, Ni, and Si. More specifically, the metal silicide film 26a is comprised of nickel silicide in which metal with a work function lower than that of Ni (for example, Ti (titanium), Hf (hafnium), Zr (zirconium), Ta (tantalum)) is solid-solved. It is considered that the metal (metal element) with a work function lower than that of Ni is solid-solved in the nickel site of the nickel silicide. Therefore, the metal silicide film 26a is composed of, for example, an Ni₁₋ₓMₓSi_{y} film (M indicates metal with a work function lower than that of Ni). This metal silicide film 26a is to be the gate electrode 31a of the n channel MISFET 30a. Since the gate electrode 31a of the n channel MISFET 30a is composed of the metal silicide film 26a (showing metallic conduction), the gate electrode 31a is a metal gate electrode.

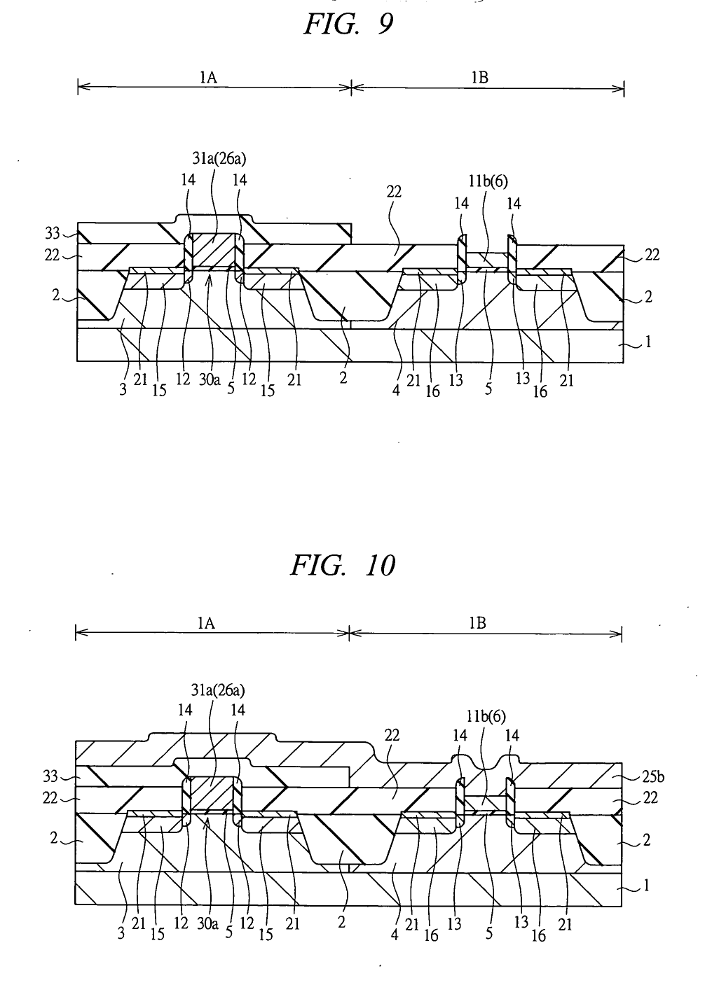

Next, as shown in FIG. 9, an insulating film 33 which covers the n channel MISFET forming region 1A including on the gate electrode 31a but not covers the p channel MISFET forming region 1B is formed on the insulating film 22. Thereafter, the insulating film 7 on the gate electrode 11b is etched and removed to expose the (upper) surface of the gate electrode 11b. For example, the insulating film 7 on the gate electrode 11b can be removed by the wet etching using hydrofluoric acid. Similar to the etching process of the insulating film 7 on the gate electrode 11a, the insulating film 22 and the sidewalls 14 are not removed when the insulating film 7 on the gate electrode 11b is etched and removed. Also, since the n channel MISFET forming region 1A is covered with the insulating film 33, the gate electrode 31a is not damaged by the etching. Also, in the case where the influence of the etching process on the gate electrode 31a does not cause any problem, the process for forming the insulating film 33 can be omitted.

Next, as shown in FIG. 10, a metal film 25b is formed on the semiconductor substrate 1. More specifically, the metal film 25b is formed on the semiconductor substrate 1 including on an upper surface of the gate electrode 11b. The metal film 25b can be formed by, for example, the sputtering method. Since the metal film 25b is formed after removing the insulating film 7 on the gate electrode 11b to expose the (upper) surface of the gate electrode 11b, the upper surface of the gate electrode 11b composed of the silicon film 6 is brought into contact with the metal film 25b.

The metal film 25b is composed of an Ni (nickel) film in which metal with a work function higher than that of Ni (nickel) (for example, Pt (platinum), Ir (iridium), or Ru (ruthenium)) is solid-solved. More specifically, the metal film 25b is composed of a metal film containing (as constituents) metal with a work function higher than that of Ni (nickel) (for example, Pt (platinum), Ir (iridium), or Ru (ruthenium)) and Ni (nickel) and is a metal alloy film of the metal with a work function higher than that of Ni and Ni.

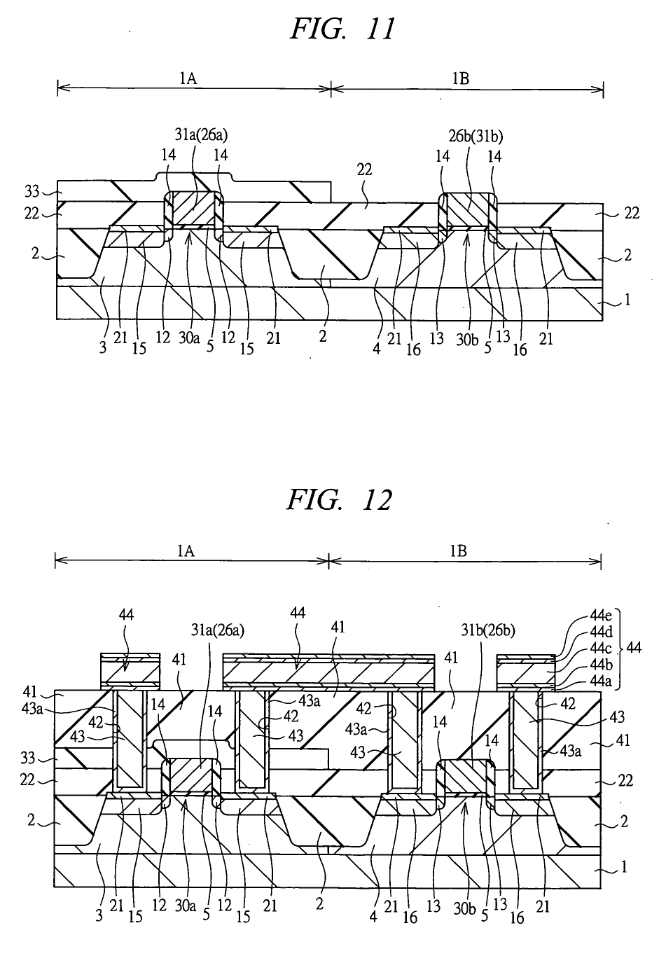

After forming the metal film 25b, the metal film 25b and the gate electrode 11b (silicon film 6) are reacted by the thermal treatment to form a metal silicide film (conductive film) 26b as shown in FIG. 11. For example, by the thermal treatment at about 400° C. in the nitrogen gas atmosphere, the metal film 25b is reacted with the gate electrode 11b (silicon film 6) to form the metal silicide film 26b. At this time, all of the silicon film 6 constituting the gate electrode 11b is completely reacted with the metal film 25b to form the metal silicide film 26b. Thereafter, the unreacted metal film 25b is removed. For example, the unreacted metal film 25b can be removed by the SPM process.

As described above, since the metal film 25b is composed of an Ni film in which the metal (metal element) with a work function higher than that of Ni is solid-solved, the metal silicide film 26b formed by the reaction between the metal film 25b and the silicon film 6 constituting the gate electrode 11b is composed of a metal silicide film containing (as constituents) Ni (nickel), metal with a work function higher than that of Ni (for example, Pt (platinum), Ir (iridium), or Ru (ruthenium)), and Si (silicon). For example, it is comprised of metal alloy of metal with a work function higher than that of Ni, Ni, and Si. More specifically, the metal silicide film 26b is comprised of nickel silicide in which metal with a work function higher than that of Ni (for example, Pt (platinum), Ir (iridium), or Ru (ruthenium)) is solid-solved. It is considered that the metal (metal element) with a work function higher than that of Ni is solid-solved in the nickel site of the nickel silicide. Therefore, the metal silicide film 26b is composed of, for example, an Ni₁₋ₓMₓSi_{y} film (M indicates metal with a work function higher than that of Ni). This metal silicide film 26b is to be the gate electrode 31b of the p channel MISFET 30b. Since the gate electrode 31b of the p channel MISFET 30b is composed of the metal silicide film 26b (showing metallic conduction), the gate electrode 31b is a metal gate electrode.

Note that, in this embodiment, the gate electrode 11a is first reacted with the metal film 25a to form the gate electrode 31a and then the gate electrode 11b is reacted with the metal film 25b to form the gate electrode 31b. However, as another embodiment, the gate electrodes 31a and 31b can be formed in the opposite order. That is, the gate electrode 11b is first reacted with the metal film 25b to form the gate electrode 31b and then the gate electrode 11a is reacted with the metal film 25a to form the gate electrode 31a.

Also, in still another embodiment, after forming the metal film 25a on the semiconductor substrate 1 including on the upper surface of the gate electrode 11a, the metal film 25a on the p channel MISFET forming region 1B is removed (the metal film 25a on the n channel MISFET forming region 1A is not removed), and then, the metal film 25b is formed on the semiconductor substrate 1 including on the upper surface of the gate electrode 11b. Thereafter, through the same thermal treatment process, the gate electrode 11a is reacted with the metal film 25a to form the gate electrode 31a and the gate electrode 11b is reacted with the metal film 25b to form the gate electrode 31b.

Next, as shown in FIG. 12, an insulating film 41 is formed on the semiconductor substrate 1. More specifically, the insulating film 41 is formed on the semiconductor substrate 1 (on the insulating film 22) so as to cover the gate electrodes 31a and 31b. It is also possible to form the insulating film 41 after removing the insulating film 33. The insulating film 41 is composed of, for example, a silicon oxide film (TEOS oxide film or the like). Then, the upper surface of the insulating film 41 is planarized by the CMP method according to need.

Next, the insulating films 22, 33, and 41 are dry-etched with using a photoresist pattern (not shown) formed on the insulating film 41 by the photolithography method as an etching mask. By doing so, contact holes (opening) 42 are formed on the n⁺ type semiconductor regions 15 (source, drain), the p⁺ type semiconductor regions 16 (source, drain), and the gate electrodes 31a and 31b. A part of the main surface of the semiconductor substrate 1, for example, a part of (the metal silicide film 21 on the surface of) the n⁺ type semiconductor region 15, a part of (the metal silicide film 21 on the surface of) the p⁺ type semiconductor region 16, or a part of the gate electrodes 31a and 31b is exposed at the bottom portions of the contact holes 42. Note that, in the cross-sectional view in FIG. 12, a part of (the metal silicide film 21 on the surface of) the n⁺ type semiconductor region 15 and a part of (the metal silicide film 21 on the surface of) the p⁺ type semiconductor region 16 are exposed at the bottom portions of the contact holes 42. However, the contact holes 42 are formed also on the gate electrodes 31a and 31b in the other region (in the cross section not shown), and the part of the gate electrodes 31a and 31b is exposed at the bottom portions of the contact holes 42.

Next, a plug 43 comprised of tungsten (W) is formed in the contact hole 42. The plug 43 is formed in the following manner. For example, after forming a barrier film (for example, titanium nitride film) 43a on the insulating film 41 and in the contact holes 42, a tungsten film is formed on the barrier film 43a by the CVD method so as to fill the contact holes 42, and the unnecessary tungsten film and barrier film 43a on the insulating film 41 are removed by the CMP method or the etch-back method.

Next, a wiring (first wiring layer) 44 is formed on the insulating film 41 in which the plugs 43 are embedded. The wiring 44 is formed in the following manner. For example, after sequentially forming a titanium film 44a, titanium nitride film 44b, an aluminum film 44c, a titanium film 44d, and a titanium nitride film 44e by the sputtering method, the films are patterned by the photolithography method and the dry etching. The aluminum film 44c is a conductive film mainly comprised of aluminum such as single aluminum (Al) or aluminum alloy. The wiring 44 is electrically connected to the n⁺ type semiconductor regions 15 to be the source and the drain of the n channel MISFET 30a, the p⁺ type semiconductor regions 16 to be the source and the drain of the p channel MISFET 30b, the gate electrode 31a of the n channel MISFET 30a, or the gate electrode 31b of the p channel MISFET 30b via the plugs 43. The wiring 44 is not limited to the above-described aluminum wiring but can be changed to various types of other wirings. For example, a tungsten wiring and a copper wiring (for example, buried copper wiring formed by the damascene method) are also available. Thereafter, an interlayer insulating film and an upper wiring layer are further formed. However, the description thereof is omitted here. The embedded copper wirings formed by the damascene method can be used as the second and subsequent layer wirings.

The semiconductor device according to this embodiment manufactured through the process described above is provided with a CMISFET having the n channel MISFET 30a and the p channel MISFET 30b formed on the main surface of the semiconductor substrate 1, and the gate electrodes 31a and 31b of the MISFETs 30a and 30b are the metal gate electrodes composed of the metal silicide films 26a and 26b.

As described above, the gate electrode 31a (that is, metal silicide film 26a) of the n channel MISFET 30a is formed by the reaction between the metal film 25a which is an Ni film in which metal (metal element) with a work function lower than that of Ni is solid-solved (contained) and the silicon film 6 constituting the gate electrode 11a, and is comprised of metal silicide containing (as constituent elements) Ni (nickel), metal with a work function lower than that of Ni (for example, Ti (titanium), Hf (hafnium), Zr (zirconium), or Ta (tantalum)), and Si (silicon). For example, it is comprised of metal alloy of metal with a work function lower than that of Ni, Ni, and Si. More specifically, the gate electrode 31a of the n channel MISFET 30a is comprised of nickel silicide in which metal with a work function lower than that of Ni (for example, Ti (titanium), Hf (hafnium), Zr (zirconium), Ta (tantalum)) is solid-solved. Since it is considered that the metal (metal element) with a work function lower than that of Ni is solid-solved in the nickel site of the nickel silicide, the gate electrode 31a of the n channel MISFET 30a is composed of, for example, an Ni₁₋ₓMₓSi_{y} film (M indicates metal with a work function lower than that of Ni).

On the other hand, the gate electrode 31b (that is, metal silicide film 26b) of the p channel MISFET 30b is formed by the reaction between the metal film 25b which is an Ni film in which metal (metal element) with a work function higher than that of Ni is solid-solved (contained) and the silicon film 6 constituting the gate electrode 11b, and is composed of a metal silicide film containing (as constituent elements) Ni (nickel), metal with a work function higher than that of Ni (for example, Pt (platinum), Ir (iridium), Ru (ruthenium)), and Si (silicon). For example, it is comprised of metal alloy of metal with a work function higher than that of Ni, Ni, and Si. More specifically, the gate electrode 31b of the p channel MISFET 30b is comprised of nickel silicide in which metal with a work function higher than that of Ni (for example, Pt (platinum), Ir (iridium), Ru (ruthenium)) is solid-solved. Since it is considered that the metal (metal element) with a work function higher than that of Ni is solid-solved in the nickel site of the nickel silicide, the gate electrode 31b of the p channel MISFET 30b is composed of, for example, an Ni₁₋ₓMₓSi_{y} film (M indicates metal with a work function higher than that of Ni).

As described above, since metal (metal element) with a work function lower than that of Ni is contained (solid-solved) in the gate electrode 31a (metal silicide film 26a) of the n channel MISFET 30a, the work function of the gate electrode 31a (metal silicide film 26a) of the n channel MISFET 30a is lower than that of nickel silicide (NiSi_{y}). On the other hand, since metal (metal element) with a work function higher than that of Ni is contained (solid-solved) in the gate electrode 31b (metal silicide film 26b) of the p channel MISFET 30b, the work function of the gate electrode 31b (metal silicide film 26b) of the p channel MISFET 30b is higher than that of nickel silicide (NiSi_{y}). Consequently, the work function of the gate electrode 31a of the n channel MISFET 30a is lower than that of the gate electrode 31b of the p channel MISFET 30b.

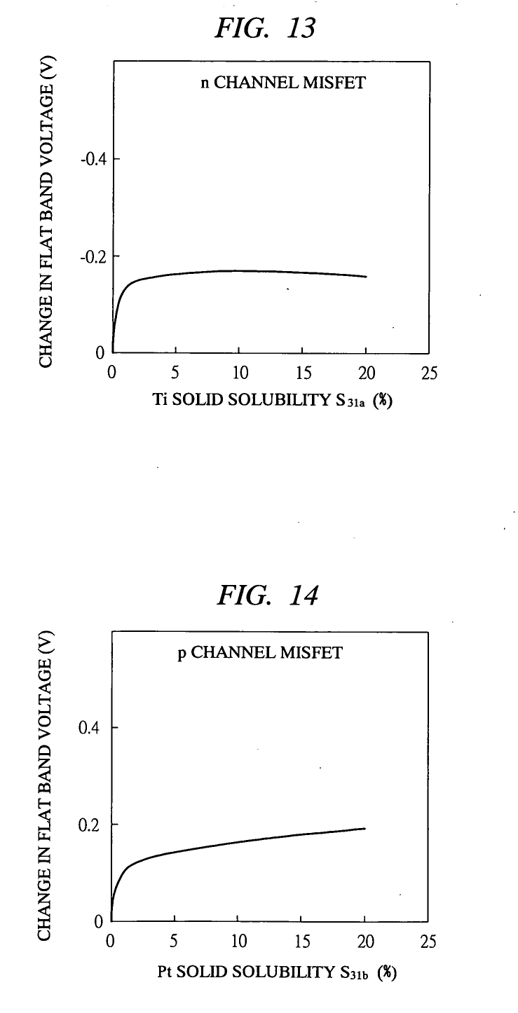

FIG. 13 is a graph showing the correlation between the solid solubility of Ti and flat band voltage when Ti which is a kind (an example) of metal with a work function lower than that of Ni is solid-solved in nickel silicide in the gate electrode 31a of the n channel MISFET 30a. FIG. 14 is a graph showing the correlation between the solid solubility of Pt and flat band voltage when Pt which is a kind (an example) of metal with a work function higher than that of Ni is solid-solved in nickel silicide in the gate electrode 31b of the p channel MISFET 30b. The horizontal axis of FIG. 13 corresponds to the solid solubility of Ti and the horizontal axis of FIG. 14 corresponds to the solid solubility of Pt. Also, the vertical axes of FIGS. 13 and 14 correspond to the change of the flat band voltage and represent the change amount of the flat band voltage from the reference flat band voltage of nickel silicide (Ti and Pt are not solid-solved) when Ti (FIG. 13) or Pt (FIG. 14) is solid-solved. The change amount of the flat band voltage almost corresponds to the change amount of threshold voltage of the MISFET. More specifically, in the case where the flat band voltage is changed by −0.2 V when Ti is solid-solved in the gate electrode 31a of the n channel MISFET 30a in FIG. 13, the threshold voltage of the n channel MISFET 30a is changed by about −0.2 V (in this case, since the threshold voltage of the n channel MISFET 30a is a positive number, the absolute value of the threshold voltage of the n channel MISFET 30a is reduced by about 0.2 V and the reduction of the threshold voltage can be achieved). Also, in the case where the flat band voltage is changed by 0.2 V when Pt is solid-solved in the gate electrode 31b of the p channel MISFET 30b in FIG. 14, the threshold voltage of the p channel MISFET 30b is changed by about 0.2 V (in this case, since the threshold voltage of the p channel MISFET 30b is a negative number, the absolute value of the threshold voltage of the p channel MISFET 30b is reduced by about 0.2 V and the reduction of the threshold voltage can be achieved).

The solid solubility S₃₁ₐ (corresponding to horizontal axis of FIG. 13) of the metal with a work function lower than that of Ni in the gate electrode 31a of the n channel MISFET 30a can be expressed as S₃₁ₐ=N_{M1}/(N_{M1}+N_{Ni})×100%. Here, N_{M1} corresponds to the number of atoms of metal (Ti in FIG. 13) with a work function lower than that of Ni in the gate electrode 31a, and N_{Ni} corresponds to the number of Ni atoms in the gate electrode 31a. More specifically, the solid solubility S₃₁ₐ of metal (Ti in FIG. 13) with a work function lower than that of Ni in the gate electrode 31a corresponds to the ratio of the number of atoms N_{M1} of the metal with a work function lower than that of Ni to the sum (N_{M1}+N_{Ni}) of the number of Ni atoms N_{Ni} and the number of atoms N_{M1} of metal (Ti in FIG. 13) with a work function lower than that of Ni in the gate electrode 31a. Also, when the metal silicide film 26a constituting the gate electrode 31a of the n channel MISFET 30a is expressed as Ni₁₋ₓMₓSi_{y} film (M indicates metal with a work function lower than that of Ni), the ratio x of the metal M converted into percentage corresponds to the solid solubility S₃₁ₐ of the metal M (that is, S₃₁ₐ=x×100%).

Similarly, the solid solubility S_{31b} (corresponding to horizontal axis of FIG. 14) of the metal with a work function higher than that of Ni in the gate electrode 31b of the p channel MISFET 30b can be expressed as S_{31b}=N_{M2}/(N_{M2}+N_{Ni})×100%. Here, N_{M2} corresponds to the number of atoms of metal (Pt in FIG. 14) with a work function higher than that of Ni in the gate electrode 31b, and N_{Ni} corresponds to the number of Ni atoms in the gate electrode 31b. More specifically, the solid solubility S_{31b} of metal (Pt in FIG. 14) with a work function lower than that of Ni in the gate electrode 31b corresponds to the ratio of the number of atoms N_{M2} of the metal with a work function higher than that of Ni to the sum (N_{M2}+N_{Ni}) of the number of Ni atoms N_{Ni} and the number of atoms N_{M2} of metal (Pt in FIG. 14) with a work function higher than that of Ni in the gate electrode 31b. Also, when the metal silicide film 26b constituting the gate electrode 31b of the p channel MISFET 30b is expressed as Ni₁₋ₓMₓSi_{y} film (M indicates metal with a work function higher than that of Ni), the ratio x of the metal M converted into percentage corresponds to the solid solubility S_{31b} of the metal M (that is, S_{31b}=x×100%).

As shown in FIG. 13, when metal (Ti in FIG. 13) with a work function lower than that of Ni is solid-solved (contained) in the gate electrode 31a of the n channel MISFET 30a, the flat band voltage (work function) of the gate electrode 31a can be reduced, and thus, the absolute value of the threshold voltage of the n channel MISFET 30a can be reduced (reduction of threshold voltage can be achieved). Also, as shown in FIG. 14, when metal (Pt in FIG. 14) with a work function lower than that of Ni is solid-solved (contained) in the gate electrode 31b of the p channel MISFET 30b, the flat band voltage (work function) of the gate electrode 31b can be increased, and thus, the absolute value of the threshold voltage of the p channel MISFET 30b can be reduced (reduction of threshold voltage can be achieved).

Also, in the gate electrode 31a of the n channel MISFET 30a, the solid solubility S₃₁ₐ of metal with a work function lower than that of Ni (that is, the ratio of the number of atoms N_{M1} of the metal with a work function lower than that of Ni to the sum of the number of N_{Ni} atoms Ni and the number of atoms N_{M1} of metal with a work function lower than that of Ni in the gate electrode 31a) is preferably set in the range of 0.1 to 20% and is more preferably set in the range of 0.2 to 10%. By setting the solid solubility S₃₁ₐ of metal with a work function lower than that of Ni preferably to 0.1% or more and more preferably to 0.2% or more in the gate electrode 31a of the n channel MISFET 30a, the flat band voltage (work function) of the gate electrode 31a of the n channel MISFET 30a can be appropriately reduced, and thus, the absolute value of the threshold voltage of the n channel MISFET 30a can be appropriately reduced. In addition, if the Ni concentration (Ni content) of the metal film 25a is too low, when the silicon film 6 constituting the gate electrode 11a is reacted with the metal film 25a to form the gate electrode 31a, the silicidation reaction is suppressed, and as a result, the unreacted silicon may be left in the gate electrode 31a. For its prevention, the Ni concentration (Ni content) of the metal film 25a is controlled to a certain level or higher (preferably to 80 atom % or higher, more preferably 90 atom % or higher) so that the solid solubility S₃₁ₐ of metal with a work function lower than that of Ni in the gate electrode 31a of the n channel MISFET 30a can be controlled to 20% or lower, more preferably, to 10% or lower. By doing so, the silicidation reaction can be appropriately performed when the silicon film 6 constituting the gate electrode 11a is reacted with the metal film 25a to form the gate electrode 31a, and thus, it is possible to prevent the unreacted silicon from being left in the gate electrode 31a. In addition, since the silicon film 6 can be sufficiently reacted with the metal film 25a to form the gate electrode 31a at a relatively low temperature, the reaction between the gate insulating film 5 and the semiconductor substrate 1 and the reaction between the gate insulating film 5 and the silicon film 6 during the process can be prevented.

Also, in the gate electrode 31b of the p channel MISFET 30b, the solid solubility S_{31b} of metal with a work function higher than that of Ni (that is, the ratio of the number of atoms N_{M2} of the metal with a work function higher than that of Ni to the sum of the number of N_{Ni} atoms Ni and the number of atoms N_{M2} of metal with a work function higher than that of Ni in the gate electrode 31b) is preferably set in the range of 0.1 to 20% and is more preferably set in the range of 0.2 to 10%. By setting the solid solubility S_{31b} of metal with a work function higher than that of Ni preferably to 0.1% or more and more preferably to 0.2% or more in the gate electrode 31b of the p channel MISFET 30b, the flat band voltage (work function) of the gate electrode 31b of the p channel MISFET 30b can be appropriately increased, and thus, the absolute value of the threshold voltage of the p channel MISFET 30b can be appropriately reduced. In addition, if the Ni concentration (Ni content) of the metal film 25b is too low, when the silicon film 6 constituting the gate electrode 11b is reacted with the metal film 25b to form the gate electrode 31b, the silicidation reaction is suppressed, and as a result, the unreacted silicon may be left in the gate electrode 31b. For its prevention, the Ni concentration (Ni content) of the metal film 25b is controlled to a certain level or higher (preferably to 80 atom % or higher, more preferably 90 atom % or higher) so that the solid solubility S_{31b} of metal with a work function higher than that of Ni in the gate electrode 31b of the p channel MISFET 30b can be controlled to 20% or lower, more preferably, to 10% or lower. By doing so, the silicidation reaction can be appropriately performed when the silicon film 6 constituting the gate electrode 11b is reacted with the metal film 25b to form the gate electrode 31b, and thus, it is possible to prevent the unreacted silicon from being left in the gate electrode 31b. In addition, since the silicon film 6 can be sufficiently reacted with the metal film 25b to form the gate electrode 31b at a relatively low temperature, the reaction between the gate insulating film 5 and the semiconductor substrate 1 and the reaction between the gate insulating film 5 and the silicon film 6 during the process can be prevented.

According to this embodiment described above, in the n channel MISFET 30a, metal with a work function lower than that of Ni is contained (solid-solved) in the gate electrode 31a mainly comprised of nickel silicide to adjust the work function (flat band voltage) of the gate electrode 31a (to be lower than that of nickel silicide), thereby controlling the threshold voltage of the n channel MISFET 30a (reducing the threshold voltage). Also, in the p channel MISFET 30b, metal with a work function higher than that of Ni is contained (solid-solved) in the gate electrode 31b mainly comprised of nickel silicide to adjust the work function (flat band voltage) of the gate electrode 31b (to be higher than that of nickel silicide), thereby controlling the threshold voltage of the p channel MISFET 30b (reducing the threshold voltage). As a result, the threshold voltage of the n channel MISFET 30a and the p channel MISFET 30b of the CMISFET can be reduced. Consequently, the performance of a semiconductor device having the CMISFET can be improved. In addition, it is possible to acquire a semiconductor device having the CMISFET with large On-current and low threshold voltage. Furthermore, the gate electrodes 31a and 31b with good symmetry can be located around midgap, and thus, the CMISFET with good characteristics can be acquired.

Also, in the case where the silicon film 6 constituting the gate electrode 11b of the p channel MISFET is a silicon film introduced (doped) with a p type impurity, in particular, B (boron) (for example, B doped polysilicon film) unlike this embodiment, there is the possibility that the p type impurity (boron) in the silicon film constituting the gate electrode 11b of the p channel MISFET penetrates through the gate insulating film 5 and diffuses in the channel region below the gate insulating film 5 in the annealing process for activating the impurity introduced in the silicon film 6, the n³¹ type semiconductor region 12, the p⁻ type semiconductor region 13, the n⁺ type semiconductor region 15, and the p⁺ type semiconductor region 16. This probably deteriorates the performance and reliability of the semiconductor device.

Meanwhile, according to this embodiment, since the silicon film 6 is reacted with the metal film 25a which is an Ni film in which metal with a work function lower than that of Ni is contained (solid-solved) to form the gate electrode 31a of the n channel MISFET 30a, the metal with a work function lower than that of Ni is contained (solid-solved) in the gate electrode 31a. By doing so, the work function (flat band voltage) of the gate electrode 31a is adjusted (to be lower than that of nickel silicide) to control the threshold voltage of the n channel MISFET 30a (reduce the threshold voltage). Also, since the silicon film 6 is reacted with the metal film 25b which is an Ni film in which metal with a work function higher than that of Ni is contained (solid-solved) to form the gate electrode 31b of the p channel MISFET 30b, the metal with a work function higher than that of Ni is contained (solid-solved) in the gate electrode 31b. By doing so, the work function (flat band voltage) of the gate electrode 31b is adjusted (to be lower than that of nickel silicide) to control the threshold voltage of the p channel MISFET 30b (reduce the threshold voltage). Therefore, a nondope silicon film doped with no impurity (for example, nondope polysilicon film or nondope amorphous silicon film) can be used as the silicon film 6. By using the nondope silicon film in which no impurity is introduced as the silicon film 6, it is possible to prevent the p type impurity (boron or the like) from penetrating through the gate insulating film 5 and diffusing in the channel region below the gate insulating film 5 in the annealing process for activating the impurity introduced in the n⁻ type semiconductor region 12, the p⁻ type semiconductor region 13, the n⁺ type semiconductor region 15, and the p⁺ type semiconductor region 16. Therefore, it is possible to improve the performance and reliability of the semiconductor device.

Furthermore, according to this embodiment, the solid solubility S₃₁ₐ of metal with a work function lower than that of Ni in the gate electrode 31a can be controlled by adjusting the content (concentration) of metal with a work function lower than that of Ni in the metal film 25a, and the solid solubility S_{31b} of metal with a work function higher than that of Ni in the gate electrode 31b can be controlled by adjusting the content (concentration) of metal with a work function higher than that of Ni in the metal film 25b. Therefore, it is possible to easily control the threshold voltage of the n channel MISFET 30a and the p channel MISFET 30b.

Also, when a metal film is directly formed on the gate insulating film 5 by the sputtering method unlike this embodiment, there is the possibility that the gate insulating film 5 is damaged. However, in this embodiment, the silicon film 6 is formed on the gate insulating film 5 by the CVD method, and the silicon film 6 is reacted with the metal films 25a and 25b formed thereon to form the gate electrodes 31a and 31b composed of the metal silicide films 26a and 26b. Therefore, it is possible to prevent the gate insulating film 5 from being damaged.

Also, since an Ni containing film (Ni alloy) mainly comprised of Ni (nickel) is used for the metal films 25a and 25b in this embodiment, the full silicidation reaction can be comprised by the thermal treatment at a relatively low temperature. More specifically, the temperature of the thermal treatment in which the silicon film 6 (gate electrodes 11a and 11b) is reacted with the metal films 25a and 25b to form the metal silicide films 26a and 26b (gate electrodes 31a and 31b) can be comprised relatively low. In addition, all of the silicon film 6 constituting the gate electrodes 11a and 11b can be reacted with the metal films 25a and 25b to form the metal silicide films 26a and 26b (gate electrodes 31a and 31b), and therefore, it is possible to prevent the unreacted silicon film 6 from being left on the gate insulating film 5. Furthermore, it is possible to suppress or prevent the reaction between the gate insulating film 5 and the semiconductor substrate 1 and between the gate insulating film 5 and the silicon film 6 in the thermal treatment process. As a result, the performance and reliability of the semiconductor device can be further improved.

Also, when the source and drain regions are formed after forming the metal gate electrodes unlike this embodiment, there is the possibility that the electrical characteristics of the MISFET are deteriorated because the metal constituting the gate electrode is reacted with the gate insulating film, the gate electrode is peeled from the gate insulating film, or the metal atoms of the gate electrode are diffused in the gate insulating film and the silicon substrate in the high-temperature annealing for activating the impurity introduced into the source and drain regions by the ion implantation method (activation annealing). In this embodiment, after the annealing process for activating the impurity introduced (ion-implanted) into the source and drain regions (n⁻ type semiconductor region 12, p⁻ type semiconductor region 13, n⁺ type semiconductor region 15, and p⁺ type semiconductor region 16) of the MISFET, the silicon film 6a (gate electrodes 11a and 11b) is reacted with the metal films 25a and 25b formed thereon to form the gate electrodes 31a and 31b composed of the metal silicide films 26a and 26b. Therefore, it is possible to prevent the reaction between the gate electrode and the gate insulating film, the peeling of the gate electrode from the gate insulating film, and the diffusion of metal atoms of the gate electrode into the gate insulating film and the silicon substrate in the annealing process for activating the impurity. As a result, the deterioration of the electrical characteristics of the MISFET can be prevented.

Also, in this embodiment, after forming the gate electrodes 11a and 11b composed of the silicon film 6a, they are reacted with the metal films 25a and 25b to form the gate electrodes 31a and 31b composed of the metal silicide films 26a and 26b. Therefore, the manufacturing line and the manufacturing apparatus for a semiconductor device with a conventional polysilicon gate electrode structure can be used without modification, and the semiconductor device with a metal gate electrode structure can be easily manufactured at low cost.

### Second Embodiment

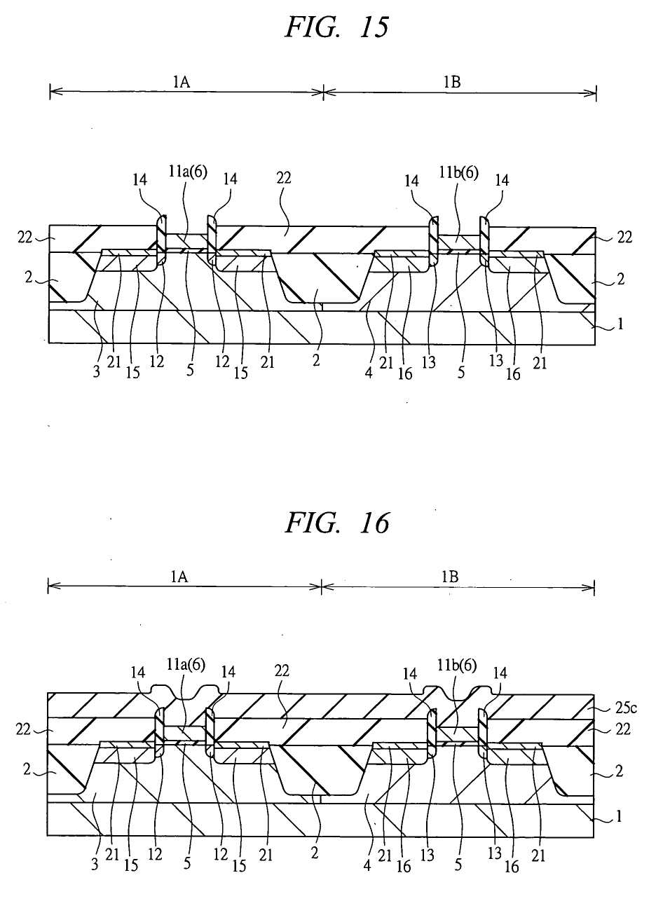

FIGS. 15 to 20 are cross-sectional views showing the principal part in the process of a manufacturing of a semiconductor device according to another embodiment of the present invention. Since the process of a manufacturing until FIG. 5 is identical to that described in the first embodiment, the description thereof is omitted here, and the process of a manufacturing after FIG. 5 will be described below.

After forming the structure shown in FIG. 5 through the process described in the first embodiment, as shown in FIG. 15, the insulating film 7 on the gate electrodes 11a and 11b is etched and removed to expose the surfaces (upper surface) of the gate electrodes 11a and 11b. For example, the insulating film 7 on the gate electrodes 11a and 11b can be removed by the wet etching using hydrofluoric acid.

Next, as shown in FIG. 16, a metal film (Ni film) 25c is formed on the semiconductor substrate 1. More specifically, the metal film (Ni film) 25c is formed on the semiconductor substrate 1 including on the upper surfaces of the gate electrodes 11a and 11b. The metal film 25c is preferably composed of a nickel (Ni) film which is a metal film mainly comprised of nickel (Ni). The metal film 25c can be formed by, for example, the sputtering method. As described above, since the metal film 25c is formed after removing the insulating film 7 on the gate electrodes 11a and 11b to expose the surfaces (upper surface) of the gate electrodes 11a and 11b, the upper surfaces of the gate electrodes 11a and 11b composed of the silicon film 6 come into contact with the metal film 25c.

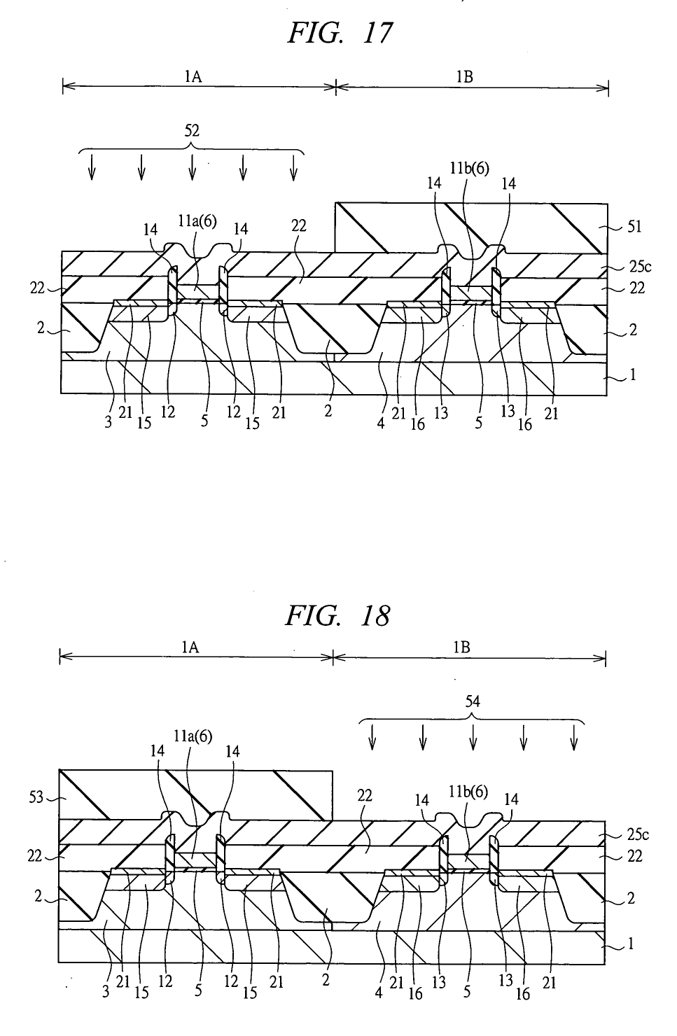

Next, as shown in FIG. 17, a mask layer (for example, photoresist pattern) 51 which covers the p channel MISFET forming region 1B but not covers the n channel MISFET forming region 1A is formed on the metal film 25c. Thereafter, metal (for example, Ti (titanium), Hf (hafnium), Zr (zirconium), Ta (tantalum)) with a work function lower than that of Ni (nickel) is introduced (ion-implanted) into the metal film 25c in the n channel MISFET forming region 1A by the ion implantation 52. At this time, the mask layer 51 prevents the metal with a work function lower than that of Ni (nickel) from being introduced into the metal film 25c in the p channel MISFET forming region 1B.

Next, as shown in FIG. 18, after removing the mask layer 51, a mask layer (for example, photoresist pattern) 53 which covers the n channel MISFET forming region 1A but not covers the p channel MISFET forming region 1B is formed on the insulating film 22. Thereafter, metal (for example, Pt (platinum), Ir (iridium), Ru (ruthenium)) with a work function higher than that of Ni (nickel) is introduced (ion-implanted) into the metal film 25c in the p channel MISFET forming region 1B by the ion implantation 54. At this time, the mask layer 53 prevents the metal with a work function higher than that of Ni (nickel) from being introduced into the metal film 25c in the n channel MISFET forming region 1A. Thereafter, the mask layer 53 is removed.

Note that, in this embodiment, the ion implantation 52 into the metal film 25c in the n channel MISFET forming region 1A is first performed and then the ion implantation 54 into the metal film 25c in the p channel MISFET forming region 1B is performed. However, as another embodiment, the ion implantations 52 and 54 can be performed in the opposite order. That is, the ion implantation 54 into the metal film 25c in the p channel MISFET forming region 1B is first performed and then the ion implantation 52 into the metal film 25c in the n channel MISFET forming region 1A is performed.

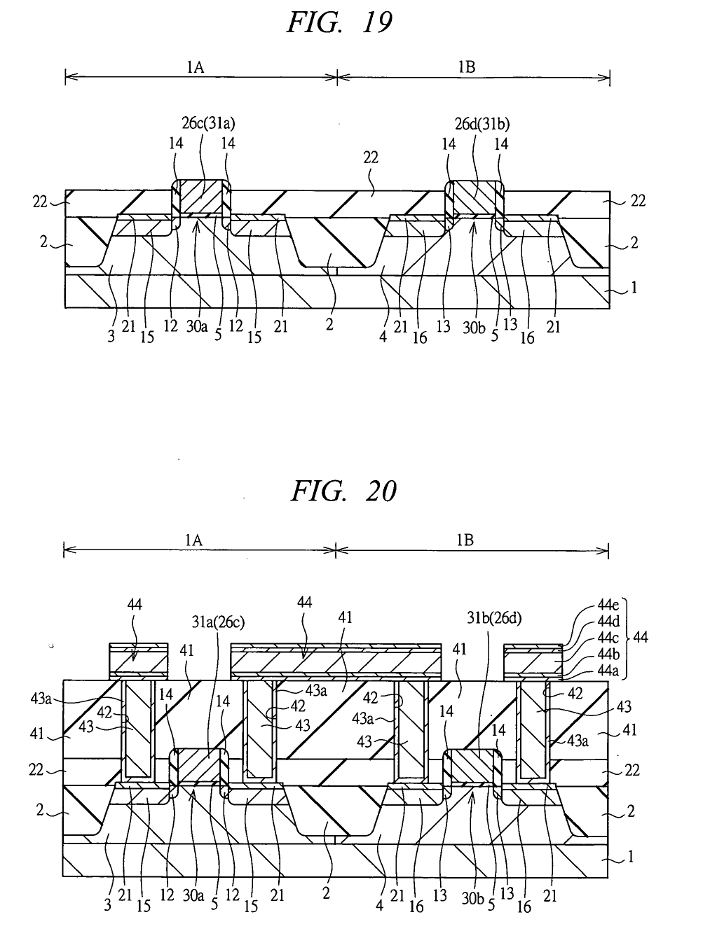

Next, as shown in FIG. 19, the metal film 25c is reacted with the gate electrodes 11a and 11b (silicon film 6) by the thermal treatment to form the metal silicide films 26c and 26d. For example, by the thermal treatment in the nitrogen gas atmosphere at about 400° C., the metal film 25c is reacted with the gate electrodes 11a and 11b (silicon film 6) to form the metal silicide films 26c and 26d. At this time, all of the silicon film 6 constituting the gate electrodes 11a and 11b is completely reacted with the metal film 25c to form the metal silicide films 26c and 26d. Thereafter, the unreacted metal film 25c is removed. For example, the unreacted metal film 25c can be removed by the SPM process.

As described above, metal (metal element) with a work function lower than that of Ni (nickel) is introduced by the ion implantation 52 into the metal film 25c in the n channel MISFET forming region 1A, and the metal film (Ni film) 25c in which metal with a work function lower than that of Ni (nickel) is introduced is reacted with the silicon film 6 constituting the gate electrode 11a to form the metal silicide film 26c. Therefore, the metal silicide film 26c is comprised of metal silicide which contains (as constituent elements) Ni (nickel), metal with a work function lower than that of Ni (for example, Ti (titanium), Hf (hafnium), Zr (zirconium), Ta (tantalum)), and Si (silicon), and is comprised of, for example, the metal alloy of these constituent elements. More specifically, the metal silicide film 26c is comprised of nickel silicide in which metal with a work function lower than that of Ni (for example, Ti (titanium), Hf (hafnium), Zr (zirconium), Ta (tantalum)) is solid-solved. It is considered that the metal (metal element) with a work function lower than that of Ni is solid-solved in the nickel site of the nickel silicide. Therefore, the metal silicide film 26c is composed of, for example, an Ni₁₋ₓMₓSi_{y} film (M indicates metal with a work function lower than that of Ni). This metal silicide film 26c is to be the gate electrode 31a of the n channel MISFET 30a. Therefore, since the gate electrode 31a of the n channel MISFET 30a is composed of the metal silicide film 26c (showing metallic conduction), the gate electrode 31a is a metal gate electrode.

Also, as described above, metal (metal element) with a work function higher than that of Ni (nickel) is introduced by the ion implantation 54 into the metal film 25c in the p channel MISFET forming region 1B, and the metal film (Ni film) 25c in which metal with a work function higher than that of Ni (nickel) is introduced is reacted with the silicon film 6 constituting the gate electrode 11b to form the metal silicide film 26d. Therefore, the metal silicide film 26d is comprised of metal silicide which contains (as constituent elements) Ni (nickel), metal with a work function higher than that of Ni (for example, Pt (platinum), Ir (iridium), or Ru (ruthenium)), and Si (silicon), and is comprised of, for example, the metal alloy of these constituent elements. More specifically, the metal silicide film 26d is comprised of nickel silicide in which metal with a work function higher than that of Ni (for example, Pt (platinum), Ir (iridium), or Ru (ruthenium)) is solid-solved. It is considered that the metal (metal element) with a work function higher than that of Ni is solid-solved in the nickel site of the nickel silicide. Therefore, the metal silicide film 26d is composed of, for example, an Ni₁₋ₓMₓSi_{y} film (M indicates metal with a work function higher than that of Ni). This metal silicide film 26d is to be the gate electrode 31b of the p channel MISFET 30b. Therefore, since the gate electrode 31b of the p channel MISFET 30b is composed of the metal silicide film 26d (showing metallic conduction), the gate electrode 31b is a metal gate electrode.

Also, in this embodiment, after the ion implantations 52 and 54 are performed to the metal film 25c composed of an Ni film, the silicon film 6 is reacted with the metal film 25c to form the gate electrodes 31a and 31b. Therefore, it is possible to form the gate electrode 31a containing metal with a work function lower than that of Ni and the gate electrode 31b containing metal with a work function higher than that of Ni in a relatively simple manufacturing process.

The subsequent manufacturing process is almost identical to that described in the first embodiment. That is, as shown in FIG. 20, the insulating film 41 is formed on the semiconductor substrate 1, and the upper surface of the insulating film 41 is planarized by the CMP method. Then, the contact holes 42, the plugs 43, and the wirings 44 are formed in the same manner as that in the first embodiment.

Also in this embodiment, the effects almost similar to those in the first embodiment can be obtained. For example, in the n channel MISFET 30a, metal with a work function lower than that of Ni is contained in the gate electrode 31a mainly comprised of nickel silicide to adjust the work function (flat band voltage) of the gate electrode 31a (to be lower than that of nickel silicide), thereby controlling the threshold voltage of the n channel MISFET 30a (reducing the threshold voltage). Also, in the p channel MISFET 30b, metal with a work function higher than that of Ni is contained in the gate electrode 31b mainly comprised of nickel silicide to adjust the work function (flat band voltage) of the gate electrode 31b (to be higher than that of nickel silicide), thereby controlling the threshold voltage of the p channel MISFET 30b (reducing the threshold voltage). As a result, the threshold voltage of the n channel MISFET 30a and the p channel MISFET 30b of the CMISFET can be reduced. Consequently, the performance of a semiconductor device having the CMISFET can be improved. In addition, it is possible to acquire a semiconductor device having the CMISFET with large On-current and low threshold voltage. Furthermore, the gate electrodes 31a and 31b with good symmetry can be located around midgap, and thus, the CMISFET with good characteristics can be acquired. In addition, since a nondope silicon film doped with no impurity can be used as the silicon film 6, it is possible to prevent the p type impurity (boron or the like) from penetrating through the gate insulating film 5 and diffusing in the channel region below the gate insulating film 5 in the annealing process for activating the impurity introduced in the n⁻ type semiconductor region 12, the p⁻ type semiconductor region 13, the n⁺ type semiconductor region 15, and the p⁺ type semiconductor region 16. Therefore, it is possible to improve the performance and reliability of the semiconductor device.

### Third Embodiment

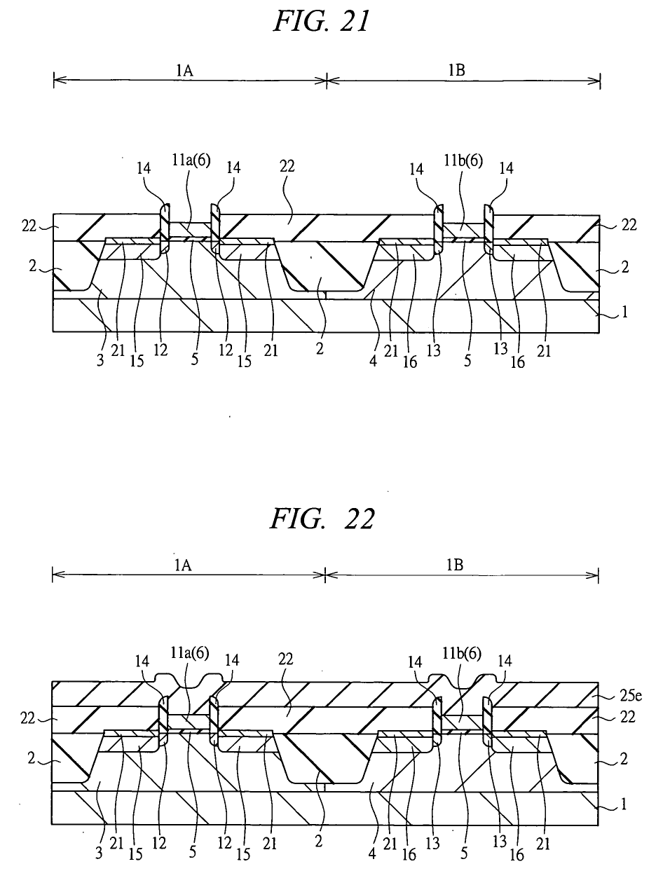

FIGS. 21 to 26 are cross-sectional views showing the principal part in the manufacturing process of a semiconductor device according to another embodiment of the present invention. Since the manufacturing process until FIG. 5 is identical to that described in the first embodiment, the description thereof is omitted here, and the manufacturing process after FIG. 5 will be described below.

After forming the structure shown in FIG. 5 through the process described in the first embodiment, as shown in FIG. 21, the insulating film 7 on the gate electrodes 11a and 11b is etched and removed to expose the surfaces (upper surface) of the gate electrodes 11a and 11b. For example, the insulating film 7 on the gate electrodes 11a and 11b can be removed by the wet etching using hydrofluoric acid.

Next, as shown in FIG. 22, a metal film (Ni film) 25e is formed on the semiconductor substrate 1. More specifically, the metal film (Ni film) 25e is formed on the semiconductor substrate 1 including on the upper surfaces of the gate electrodes 11a and 11b. The metal film 25e is preferably composed of a nickel (Ni) film which is a metal film mainly comprised of nickel (Ni). The metal film 25e can be formed by, for example, the sputtering method. As described above, since the metal film 25e is formed after removing the insulating film 7 on the gate electrodes 11a and 11b to expose the surfaces (upper surface) of the gate electrodes 11a and 11b, the upper surfaces of the gate electrodes 11a and 11b composed of the silicon film 6 come into contact with the metal film 25e. The process so far is almost identical to that in the second embodiment.

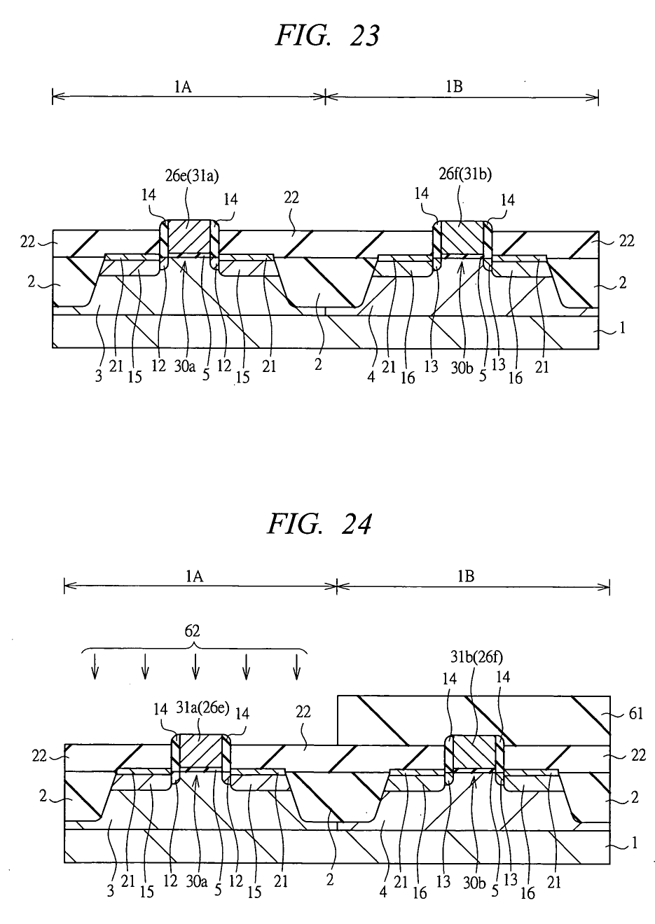

Next, as shown in FIG. 23, the metal film 25e is reacted with the gate electrodes 11a and 11b (silicon film 6) by the thermal treatment to form metal silicide films 26e and 26f. For example, by the thermal treatment at about 400° C. in the nitrogen gas atmosphere, the metal film 25e is reacted with the gate electrodes 11a and 11b (silicon film 6) to form the metal silicide films 26e and 26f. At this time, all of the silicon film 6 constituting the gate electrodes 11a and 11b is completely reacted with the metal film 25e to form the metal silicide films 26e and 26f. Since the metal film 25e is an Ni (nickel) film as described above, the metal silicide films 26e and 26f are nickel silicide (NiSi_{y}) films. Thereafter, the unreacted metal film 25e is removed. For example, the unreacted metal film 25e can be removed by the SPM process.

Next, as shown in FIG. 24, a mask layer (for example, photoresist pattern) 61 which covers the p channel MISFET forming region 1B but not covers the n channel MISFET forming region 1A is formed on the insulating film 22. Thereafter, metal (for example, Ti (titanium), Hf (hafnium), Zr (zirconium), Ta (tantalum)) with a work function lower than that of Ni (nickel) is introduced (ion-implanted) into the metal silicide film 26e in the n channel MISFET forming region 1A by the ion implantation 62. At this time, the mask layer 61 prevents the metal with a work function lower than that of Ni (nickel) from being introduced into the metal silicide film 26f in the p channel MISFET forming region 1B.

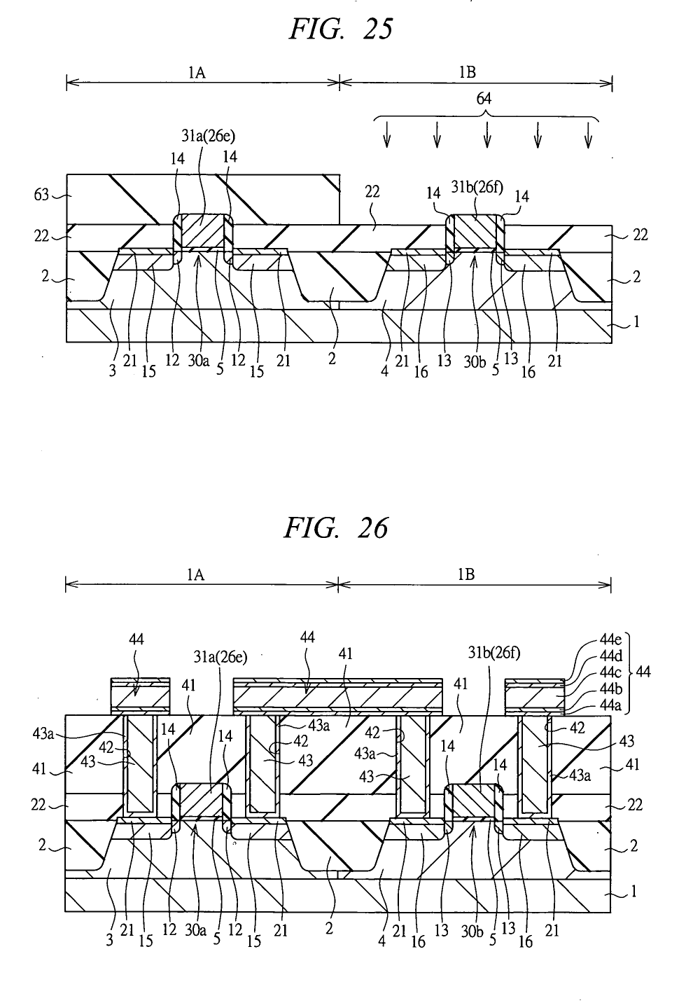

Next, as shown in FIG. 25, after removing the mask layer 61, a mask layer (for example, photoresist pattern) 63 which covers the n channel MISFET forming region 1A but not covers the p channel MISFET forming region 1B is formed on the insulating film 22. Thereafter, metal (for example, Pt (platinum), Ir (iridium), Ru (ruthenium)) with a work function higher than that of Ni (nickel) is introduced (ion-implanted) into the metal silicide film 26f in the p channel MISFET forming region 1B by the ion implantation 64. At this time, the mask layer 63 prevents the metal with a work function higher than that of Ni (nickel) from being introduced into the metal silicide film 26e in the n channel MISFET forming region 1A. Thereafter, the mask layer 63 is removed. Then, the annealing process (thermal treatment) is performed according to need so as to make the distribution of the metal introduced by the ion implantation into the metal silicide films 26e and 26f uniform.

As described above, metal (metal element) with a work function lower than that of Ni (nickel) is introduced by the ion implantation 62 into the metal silicide film 26e in the n channel MISFET forming region 1A. Therefore, the metal silicide film 26e is comprised of metal silicide which contains (as constituent elements) Ni (nickel), metal with a work function lower than that of Ni (for example, Ti (titanium), Hf (hafnium), Zr (zirconium), Ta (tantalum)), and Si (silicon). More specifically, the metal silicide film 26e is comprised of nickel silicide in which metal with a work function lower than that of Ni (for example, Ti (titanium), Hf (hafnium), Zr (zirconium), Ta (tantalum)) is introduced (solid-solved, contained). This metal silicide film 26e is to be the gate electrode 31a of the n channel MISFET 30a. Therefore, since the gate electrode 31a of the n channel MISFET is composed of the metal silicide film 26e (showing metallic conduction), the gate electrode 31a is a metal gate electrode.

Also, as described above, metal (metal element) with a work function higher than that of Ni (nickel) is introduced by the ion implantation 64 into the metal silicide film 26f in the p channel MISFET forming region 1B. Therefore, the metal silicide film 26f is comprised of metal silicide which contains (as constituent elements) Ni (nickel), metal with a work function higher than that of Ni (for example, Pt (platinum), Ir (iridium), Ru (ruthenium)), and Si (silicon). More specifically, the metal silicide film 26f is comprised of nickel silicide in which metal with a work function higher than that of Ni (for example, Pt (platinum), Ir (iridium), Ru (ruthenium)) is introduced (solid-solved, contained). This metal silicide film 26f is to be the gate electrode 31b of the p channel MISFET 30b. Therefore, since the gate electrode 31b of the p channel MISFET is composed of the metal silicide film 26f (showing metallic conduction), the gate electrode 31b is a metal gate electrode.

Note that, in this embodiment, the ion implantation 62 into the metal silicide film 26e in the n channel MISFET forming region 1A is first performed and then the ion implantation 64 into the metal silicide film 26f in the p channel MISFET forming region 1B is performed. However, as another embodiment, the ion implantations 62 and 64 can be performed in the opposite order. That is, the ion implantation 64 into the metal silicide film 26f in the p channel MISFET forming region 1B is first performed and then the ion implantation 62 into the metal silicide film 26e in the n channel MISFET forming region 1A is performed.

In this embodiment, after the silicon film 6 is reacted with the metal film 25e composed of an Ni film to form the gate electrodes 31a and 31b, the ion implantation 62 into the gate electrode 31a is performed and then the ion implantation 64 is performed to the gate electrode 31b. Therefore, it is possible to form the gate electrode 31a containing metal with a work function lower than that of Ni and the gate electrode 31b containing metal with a work function higher than that of Ni in a relatively simple manufacturing process.

The subsequent manufacturing process is almost identical to that described in the first embodiment. That is, as shown in FIG. 26, the insulating film 41 is formed on the semiconductor substrate 1, and the upper surface of the insulating film 41 is planarized by the CMP method. Then, the contact holes 42, the plugs 43, and the wirings 44 are formed in the same manner as that in the first embodiment.

Also in this embodiment, the effects almost similar to those in the first embodiment can be obtained. For example, in the n channel MISFET 30a, metal with a work function lower than that of Ni is contained in the gate electrode 31a mainly comprised of nickel silicide to adjust the work function (flat band voltage) of the gate electrode 31a (to be lower than that of nickel silicide), thereby controlling the threshold voltage of the n channel MISFET 30a (reducing the threshold voltage). Also, in the p channel MISFET 30b, metal with a work function higher than that of Ni is contained in the gate electrode 31b mainly comprised of nickel silicide to adjust the work function (flat band voltage) of the gate electrode 31b (to be higher than that of nickel silicide), thereby controlling the threshold voltage of the p channel MISFET 30b (reducing the threshold voltage). As a result, the threshold voltage of the n channel MISFET 30a and the p channel MISFET 30b of the CMISFET can be reduced. Consequently, the performance of a semiconductor device having the CMISFET can be improved. In addition, it is possible to acquire a semiconductor device having the CMISFET with large On-current and low threshold voltage. Furthermore, the gate electrodes 31a and 31b with good symmetry can be located around midgap, and thus, the CMISFET with good characteristics can be acquired. In addition, since a nondope silicon film doped with no impurity can be used as the silicon film 6, it is possible to prevent the p type impurity (boron or the like) from penetrating through the gate insulating film 5 and diffusing in the channel region below the gate insulating film 5 in the annealing process for activating the impurity introduced in the n⁻ type semiconductor region 12, the p⁻ type semiconductor region 13, the n⁺ type semiconductor region 15, and the p⁺ type semiconductor region 16. Therefore, it is possible to improve the performance and reliability of the semiconductor device.

In the foregoing, the invention comprised by the inventors of the present invention has been concretely described based on the embodiments. However, it is needless to say that the present invention is not limited to the foregoing embodiments and various modifications and alterations can be comprised within the scope of the present invention.

The present invention is effectively applied to a semiconductor device in which the gate electrodes of the MISFETs are comprised of metal silicide and a manufacturing method thereof.

1. A semiconductor device, comprising:
an n channel first MISFET; and
a p channel second MISFET,
wherein a first gate electrode of said first MISFET is comprised of metal silicide containing Ni, first metal with a work function lower than that of Ni, and Si, and
a second gate electrode of said second MISFET is comprised of metal silicide containing Ni, second metal with a work function higher than that of Ni, and Si.

2. The semiconductor device according to claim 1,
wherein said first gate electrode of said first MISFET is comprised of nickel silicide in which said first metal is solid-solved, and
said second gate electrode of said second MISFET is comprised of nickel silicide in which said second metal is solid-solved.

3. The semiconductor device according to claim 1,
wherein a work function of said first gate electrode of said first MISFET is lower than a work function of said second gate electrode of said second MISFET.

4. The semiconductor device according to claim 1,
wherein a ratio of the number of atoms of said first metal to a sum of the number of Ni atoms and the number of atoms of said first metal is in a range of 0.1% to 20% in said first gate electrode of said first MISFET, and
a ratio of the number of atoms of said second metal to a sum of the number of Ni atoms and the number of atoms of said second metal is in a range of 0.1% to 20% in said second gate electrode of said second MISFET.

5. A method of manufacturing a semiconductor device having an n channel first MISFET and a p channel second MISFET, comprising steps of:
(a) preparing a semiconductor substrate;
(b) forming a first insulating film for a gate insulating film on said semiconductor substrate;
(c) forming a silicon film on said first insulating film;
(d) forming a first dummy electrode of said first MISFET and a second dummy electrode of said second MISFET by patterning said silicon film;
(e) forming a first metal film containing Ni and first metal with a work function lower than that of Ni on said first dummy electrode;
(f) reacting said silicon film constituting said first dummy electrode with said first metal film to form a first gate electrode of said first MISFET, which is comprised of metal silicide containing Ni, said first metal, and Si;
(g) forming a second metal film containing Ni and second metal with a work function higher than that of Ni on said second dummy electrode; and
(h) reacting said silicon film constituting said second dummy electrode with said second metal film to form a second gate electrode of said second MISFET, which is comprised of metal silicide containing Ni, said second metal, and Si.

6. The method of manufacturing a semiconductor device according to claim 5,
wherein said first metal film is comprised of a nickel film in which said first metal is solid-solved,
said second metal film is comprised of a nickel film in which said second metal is solid-solved,
said first gate electrode is comprised of nickel silicide in which said first metal is solid-solved, and
said second gate electrode is comprised of nickel silicide in which said second metal is solid-solved.

7. The method of manufacturing a semiconductor device according to claim 5,
wherein said silicon film is a nondope silicon film.

8. A method of manufacturing a semiconductor device having an n channel first MISFET and a p channel second MISFET, comprising steps of:
(a) preparing a semiconductor substrate;
(b) forming a first insulating film for a gate insulating film on said semiconductor substrate;
(c) forming a silicon film on said first insulating film;
(d) forming a first dummy electrode of said first MISFET and a second dummy electrode of said second MISFET by patterning said silicon film;
(e) forming a metal film mainly comprised of nickel on said first dummy electrode and said second dummy electrode;
(f) introducing first metal with a work function lower than that of Ni into said metal film on said first dummy electrode and introducing second metal with a work function higher than that of Ni into said metal film on said second dummy electrode by ion implantation, and
(g) reacting said silicon film constituting said first dummy electrode with said metal film in which said first metal is introduced to form a first gate electrode of said first MISFET comprised of metal silicide containing Ni, said first metal, and Si, and reacting said silicon film constituting said second dummy electrode with said metal film in which said second metal is introduced to form a second gate electrode of said second MISFET comprised of metal silicide containing Ni, said second metal, and Si.

9. The method of manufacturing a semiconductor device according to claim 8,
wherein said first gate electrode is comprised of nickel silicide in which said first metal is solid-solved, and
said second gate electrode is comprised of nickel silicide in which said second metal is solid-solved.

10. The method of manufacturing a semiconductor device according to claim 8,
wherein said silicon film is a nondope silicon film.

11. A method of manufacturing a semiconductor device having an n channel first MISFET and a p channel second MISFET, comprising steps of:
(a) preparing a semiconductor substrate;
(b) forming a first insulating film for a gate insulating film on said semiconductor substrate;
(c) forming a silicon film on said first insulating film;
(d) forming a first dummy electrode of said first MISFET and a second dummy electrode of said second MISFET by patterning said silicon film;
(e) forming a metal film mainly comprised of nickel on said first dummy electrode and said second dummy electrode;
(f) reacting said silicon film constituting said first dummy electrode with said metal film to form a first gate electrode of said first MISFET comprised of nickel silicide, and reacting said silicon film constituting said second dummy electrode with said metal film to form a second gate electrode of said second MISFET comprised of nickel silicide; and
(g) introducing first metal with a work function lower than that of Ni into said first gate electrode and introducing second metal with a work function higher than that of Ni into said second gate electrode by ion implantation.

12. The method of manufacturing a semiconductor device according to claim 11,
wherein said silicon film is a nondope silicon film.
